(19) United States
(12) Patent Application Publication
(10) Pub. No.: US 2006/0283839 A1
(43) Pub. Date: Dec. 21, 2006

(54) Polishing equipment having a longer operating time length

(75) Inventor: Toshiya Saito, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., TOKYO (JP)

(21) Appl. No.: 11/455,176

(22) Filed: Jun. 19, 2006

(30) Foreign Application Priority Data
Jun. 20, 2005 (JP) 2005-179544
May 25, 2006 (JP) 2006-145126

(51) Int. Cl. C03C 15/00; H01L 21/306; B44C 1/22; H01L 21/302

(52) U.S. Cl. 216/84; 156/345.12; 438/692; 216/88

(57) ABSTRACT

A polishing equipment includes a polishing head mounting thereon a wafer and a polishing pad having a polishing surface for polishing the wafer. The polishing surface has a groove for guiding slurry on the polishing surface. The groove has a depth larger in the intermediate area of the polishing surface than in the central area and peripheral area of the polishing surface, in consideration of a higher abrasion rate of the polishing surface in the intermediate area in which the polishing surface is abraded in a larger amount.

### BACKGROUND OF THE INVENTION

(A) Field of the Invention

The present invention relates to a polishing equipment and, more particularly, to a polishing equipment for use in a chemical-mechanical polishing (CMP) process for polishing a semiconductor wafer. The present invention also relates to a polishing method used in the polishing equipment.

(B) Description of the Related Art

In recent years, the degree of integration of semiconductor devices has been remarkably increased to increase the number of interconnection layers in the semiconductor devices. In such a semiconductor device having a multilayer interconnection structure, each film formed therein should have a planar surface in order for limiting the surface roughness within the depth of focus of the exposure light used in a photolithographic process. One of the techniques used for planarization of the film includes a CMP process.

FIG. 18A shows an example of a polishing equipment used in the CMP process, and FIG. 18B shows a vertical sectional view taken along a plane passing through the central axis of a polishing pad therein. In the polishing equipment 100, the polishing pad 12 is fixed on to a circular table, and is rotated with respect to the central axis 11a thereof. A wafer 13 is mounted on a polishing head 14 and pressed against the top surface of the polishing pad 12 by the polishing head 14. The polishing head 14 is rotated with respect to the central axis 14a thereof to allow the main surface of the wafer 13 to be polished by the polishing pad 12.

Slurry including therein abrasive grains mixed with a polishing liquid is supplied from a slurry tube 15 at the center of the polishing pad 12, and flows toward the circumferential direction by the centrifugal force generated by the rotation of the polishing pad 12. A groove (not shown) is formed on the surface of the polishing pad 12 to guide the flow of the slurry. The wafer 13 is polished by both the chemical action of the polishing liquid and the mechanical action of the abrasive grains, which proceed concurrently.

In the polishing equipment 100, range of variation or reduction in the polishing rate may occur due to the abrasive grains or ground particles filling or blocking the minute holes formed on the surface of the polishing pad 12. This causes a difficulty in obtaining the reproducibility of the polishing rate in the polishing process. In order for achieving a constant state of the polishing pad 12 to prevent the reduction in the polishing rate, a conditioner 17 is generally used for grinding the polishing pad 12 to remove the abrasive grains or ground particles from the minute holes in the polishing pad 12.

Patent Publication JP-2002-270557A, for example, describes the CMP process, and Patent Publication JP-2003-229390A describes the treatment of a polishing pad by using the conditioner.

In the CMP process, the polishing pad is abraded due to the grinding treatment by the conditioner and the polishing treatment of the wafer. When the depth of the groove formed on the surface of the polishing pad is reduced by the abrasion, the amount of slurry supplied along the groove onto a specific area of the polishing pad 12 is reduced, thereby causing a considerable reduction of the polishing rate in the specific area. Thus, the polishing pad is discarded after a specific operating time length, in consideration of the degree of abrasion thereon. It is important in the semiconductor process to increase the operating time length of the polishing pad for achieving a higher throughput for manufacturing the semiconductor devices.

It is also important to achieve a uniform polishing rate within the surface of the wafer in the CMP process. This is because a larger range of variation in the polishing rate causes a larger range of variation in the polished film thickness and cannot achieve a uniform polished profile on the wafer. It is to be noted that the wafer is pressed against the polishing pad by both the mechanical load (F1) of the polishing head and the load (F2) of compressed air. In the conventional technique, the balance between the loads F1 and F2 is changed to control the polishing rate. However, the change of balance has a limited function in the control of the polishing rate, and thus a new technique for controlling the polishing rate in the manufacture of the semiconductor device is desired together with the recent development in the performance and quality of the semiconductor device.

### SUMMARY OF THE INVENTION

In view of the above, it is an object of the present invention to provide a polishing equipment and a polishing method which are capable of increasing the operating time length of the polishing pad.

It is another object of the present invention to provide a polishing equipment and a polishing method which are capable of reducing the range of variation in the polishing rate within the surface of the wafer to achieve a superior polished profile.

The present invention provides, in a first aspect thereof, a polishing equipment including: a polishing head for mounting thereon a wafer to be polished and rotating the wafer with respect to a central axis thereof; and a polishing pad rotating with respect to a central axis thereof and having a polishing surface for polishing a main surface of the wafer, wherein the polishing surface has thereon a plurality of convex portions defining therebetween a groove for passing therethrough slurry, and at least a widthwise portion of the groove in a first area of the polishing surface has a depth larger than a depth of a corresponding at least widthwise portion of the groove in a second area of the polishing surface.

The present invention provides, in a second aspect thereof, a polishing equipment including: a polishing head for mounting thereon a wafer to be polished and rotating the wafer with respect to a central axis thereof; and a polishing pad rotating with respect to a central axis thereof and having a polishing surface for polishing a main surface of the wafer, wherein the polishing surface includes an array of convex portions attached or formed on the polishing surface to configure therebetween a groove.

The present invention provides, in a third aspect thereof, a method for polishing an object by using a polishing equipment including a polishing head mounting thereon and rotating the object, and a polishing pad having a polishing surface for polishing a surface of the object, the method including the steps of: calculating a distance of locus of each of a plurality of points on the surface of the object apart from one another in a radial direction during moving of the each of the plurality of points upon rotation of the object and the polishing surface, the plurality of points corresponding to a plurality of areas of the polishing surface; and calculating an expected polishing rate of the each of the plurality of points based on the calculated distance.

The above and other objects, features and advantages of the present invention will be more apparent from the following description, referring to the accompanying drawings.

### BRIEF DESCRIPTION OF THE DRAWINGS

FIG. 1A is a top plan view of a polishing equipment according to a first embodiment of the present invention, and FIG. 1B is a side view thereof as viewed in the direction of in FIG. 1A.

FIG. 2A is a top plan view of the polishing pad shown in FIG. 1A, and FIG. 2B is a sectional view taken along line B-B in FIG. 2A.

FIG. 3A is a sectional view of a conventional polishing pad, and FIGS. 3B and 3C are sectional views showing abrasion during proceeding operation of the polishing pad.

FIG. 4 is a sectional view of a first modification from the polishing pad used in the first embodiment.

FIG. 5 is a sectional view of a second modification from the polishing pad in the first embodiment.

FIG. 6 is a sectional view of a polishing pad used in a polishing equipment according to a second embodiment of the present invention.

FIG. 7 is a sectional view of the polishing pad

FIG. 7 is a sectional view of the polishing pad shown in FIG. 6 in a different state thereof.

FIGS. 8A and 8B are sectional views of the polishing pad shown in FIG. 6 during the change of the state thereof.

FIG. 9 is a sectional view of a first modification from the polishing pad in the second embodiment.

FIGS. 10A to 10C are sectional views of the polishing pad, showing consecutive steps of fabrication thereof.

FIGS. 11A and 11B are sectional views showing consecutive steps of fabrication thereof.

FIG. 12A is a top plan view of a second modification from the polishing pad in the second embodiment, and FIG. 12B is a sectional view thereof.

FIG. 13A is a top plan view of a third modification from the polishing pad in the second embodiment, and FIG. 13B is a sectional view thereof.

FIG. 14A is a top plan view of a fourth modification from the polishing pad in the second embodiment, FIG. 14B is a sectional view taken along line B-B in FIG. 14A, and FIG. 14C shows the polishing pad of FIG. 14B in a different state thereof.

FIGS. 15A and 15B sectional views of the polishing pad shown in FIGS. 14A to 14B during procedure of the change of state thereof.

FIG. 16 is a top plan view of a polishing equipment used in a polishing method according to a third embodiment of the present invention.

FIG. 17 is a top plan view of the polishing equipment of FIG. 16 for showing a polishing method according to a third embodiment of the present invention.

FIG. 18A is a top plan view of a conventional polishing equipment, and FIG. 18B is a sectional view thereof.

### PREFERRED EMBODIMENTS OF THE INVENTION

Now, the present invention is more specifically described with reference to accompanying drawings, wherein similar constituent elements are designated by similar reference numerals throughout the drawings.

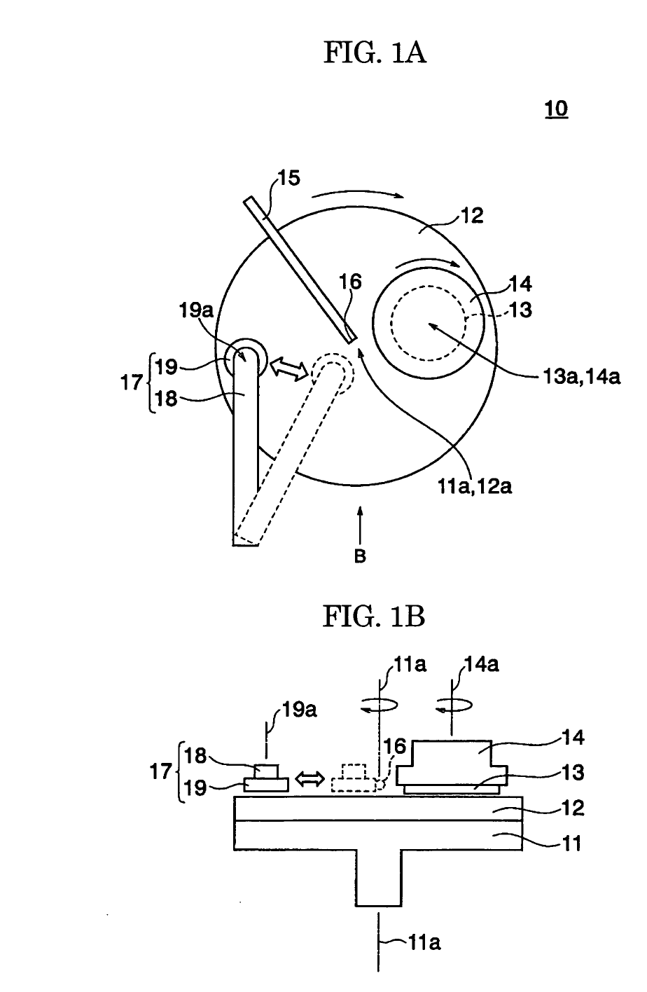

FIG. 1A shows the configuration of a polishing equipment according to a first embodiment of the present invention, and FIG. 1B is a sectional view depicting the polishing pad shown in FIG. 1A. The polishing equipment 10 of the present embodiment is used in a CMP process for polishing a wafer, and includes a disk-like table 11 which is rotated with respect to the central axis 11a thereof, and a disk-like polishing pad 12 fixed onto table 11 with the center 12a of the polishing pad 12 being aligned with the rotational axis 11a of the table. 11. The polishing pad 12 has thereon a groove (not shown) used as the passage of slurry, wherein the groove has different depths at different areas. The disk-like table 11 has a diameter of 750 mm, and rotates at a rotational speed of 30 min⁻¹, for example, in the clockwise rotation.

A polishing head 14 mounts thereon a wafer 13 between the same and the top surface of the polishing pad 12, with the center 13a of the wafer 13 being aligned with the rotational axis 14a of the polishing head 14. The polishing head 14 presses the wafer 13 toward the polishing pad 12 with a mechanical load F1 and a compressed-air load F2, wherein F1 is adjusted at 70 Newton and F2 is adjusted at 50 Newton, for example. The polishing head 14 rotates at a rotational speed of 29 min⁻¹ in the clockwise direction with respect to the rotational axis 14a, and is reciprocally moved in a radial direction of the polishing pad 12 within the range of the radius. The wafer 12 is taken out from the polishing head 14 after completion of the polishing treatment and subsequent washing treatment thereof.

On the polishing pad 12 is supported a slurry tube 15 so that the discharge port 16 of the slurry tube 15 is located at the center of the polishing pad 12. The discharge port 16 ejects the slurry onto the polishing pad 12 at a flow rate of 300 ml/min, and the ejected slurry is spread from the center of the polishing pad 12 toward the periphery thereof mainly along the groove due to the centrifugal force generated by rotation of the polishing pad 12.

A conditioner 17 is supported on the polishing pad 12. The conditioner 17 includes an arm 18 swiveling within a specific angle, and a disk-like dresser 19 rotatably mounted on the distal end of the arm 18. The dresser 19 has a bottom grinding surface onto which abrasive diamond grains, for example, are fixed. The dresser 19 rotates at a rotational speed of 25 min⁻¹ in a specific rotational direction with respect to the central axis 19a thereof. The dresser 19 is reciprocally moved by the arm 18 in the radial direction of the polishing pad 12 within the range of radius, thereby grinding the whole top surface of the polishing pad 12. The grinding by the dresser 19 removes the abrasive grains or ground particles filling the minute holes formed on the surface of the polishing pad 12, thereby maintaining the polishing rate of the wafer 13 by the polishing pad 12.

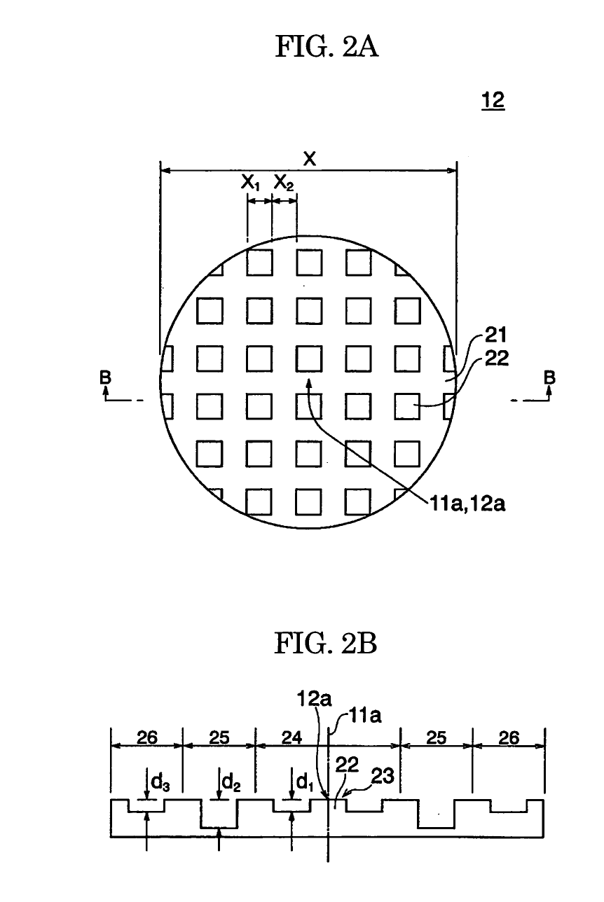

FIG. 2A depicts the top surface of the polishing pad shown in FIG. 1A, and FIG. 2B is a sectional view taken along line B-B in FIG. 2A. The top surface of the polishing pad 12 has a plurality of trenches extending parallel to one another in the row direction and the column direction to form a lattice-like groove 21. The trenches have a width (X2) of 2 mm and arranged at a pitch (X1) of 40 mm, whereby a plurality of square convex portions 22 having a side of 40 mm are formed between the trenches. The convex portions 22 have a flat top surface. The polishing pad 12 is made of polyurethane, for example.

As shown in FIG. 2B, in the central area 24 and peripheral area 26 of the polishing pad 12, the groove 21 has a depth (d1, d3) of 2 mm, whereas in the intermediate area 25, the groove 21 has a depth (d2) of 3 mm, with the top surface of the convex portions 22 being uniform within the polishing pad 12. The central area 24 has an outer radius of 150 mm, the intermediate area 25 has an inner and outer radii of 150 mm and 255 mm, and the peripheral area 26 has an inner radius of 255 mm, in the example of the present embodiment.

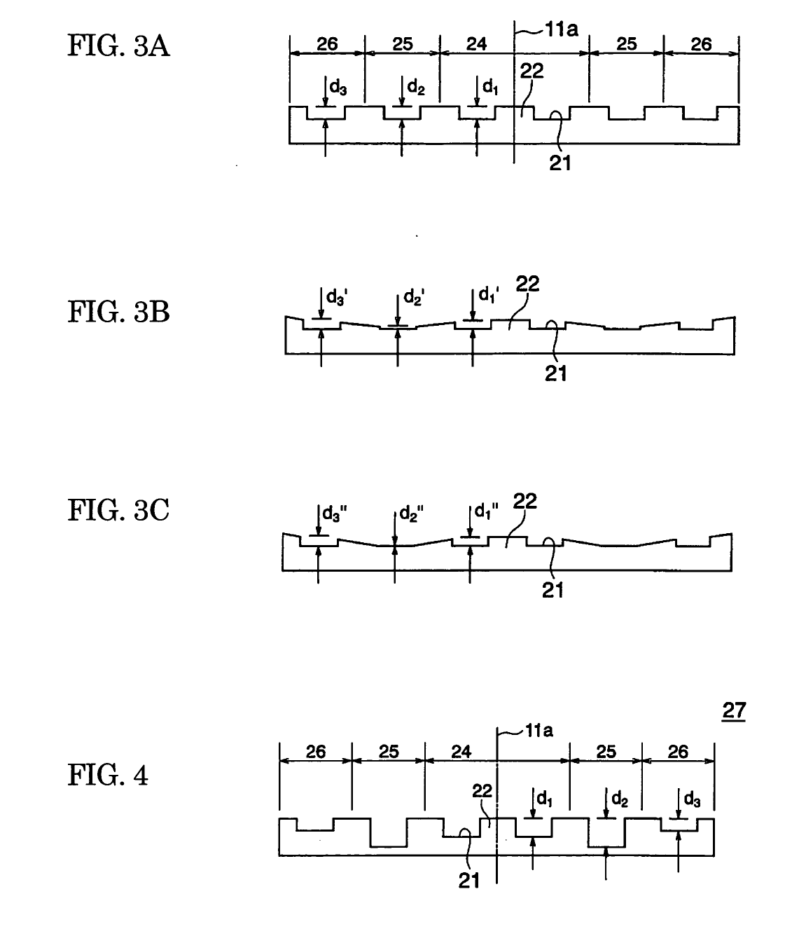

FIG. 3A shows a sectional view of a conventional polishing pad, whereas FIGS. 3B and 3C show the conventional polishing pad at steps during proceeding of abrasion. The conventional polishing pad has a groove depth of 2 mm at each of the three areas 24, 25 and 26. After some operating time length of the polishing pad 12 and dresser 19, as shown in FIG. 3B, the convex portions 22 have a largest amount of abrasion in the intermediate area 25, whereby the depth d2′ of the groove in the intermediate area 25 is smaller than the depth d1′ and d3′ in the central area 24 and peripheral area 25.

After a further operating time length of the conventional polishing pad, the groove 21 is substantially disappeared in the intermediate area 25. According to the experiments conducted by the inventor, at this stage of the polishing pad, the groove 21 in the peripheral area 26 had a depth (d3″) of about 0.8 to 1.0 mm. The distinction of the groove 21 in the intermediate area 25 impedes flow of the slurry in the intermediate area 25, whereby there arises an area to which the slurry is not supplied to thereby reduce the polishing rate therein. Thus, the conventional polishing pad is replaced at this stage by a new polishing pad.

On the other hand, in the polishing pad 12 in the polishing equipment 10 of the present embodiment, the groove 21 has a larger depth d2 in the intermediate area 25 than the depth d1, d3 in the central area 24 and peripheral area 26, whereby the groove 21 can be secured in the intermediate area 25 for a longer operating time length. For example, even after the operating time length of the polishing pad 12 corresponding to the stage shown in FIG. 3C, the polishing pad 12 in the present embodiment will have a sufficient depth of the groove 21 in the intermediate area 25, whereby a sufficient polishing rate can be maintained at this stage.

Moreover, by employing the depth d2 of the groove 21 in the intermediate area 25 which is 1 mm larger than the depth d1, d3 of the groove 21 in the central area 24 and the peripheral area 26, the convex portions 22 will be disappeared substantially at the same operating time length of the polishing pad 12 in all the areas 24 to 26. Thus, the operating time length of the polishing pad 12 can be increased to improve the throughput of the fabrication process for the semiconductor devices.

The fact that the abrasion rate of the polishing pad 12 is higher in the intermediate area 25 than in the central and peripheral areas 24, 26 is considered to result from the reason as follows. The intermediate area 25 of the polishing pad 12 mostly polishes the inner area of the wafer 13, whereas the central area 24 and peripheral area 26 mostly polish the peripheral area of the wafer 13. The moving distance of the central point and a specific peripheral point of the wafer are examined herein with respect to the surface of the polishing pad 2 for a unit operating time length. Since the polishing pad 12 and the polishing head 14 rotate in the same rotational direction, as shown in FIG. 17, the moving distance L1 of the central point of the wafer 13 within the intermediate area 25 of the polishing pad 12 during the unit time length is larger than the moving distance L2 of the specific peripheral point of the wafer 13 within the peripheral area 26 of the polishing pad 12 during the unit time length.

In addition, although not illustrated, the moving distance L1 is also longer than the moving distance L3 of the specific peripheral point of the wafer 13 within the central area 24 of the polishing pad 12. The difference between these moving distances L1, L2, L3 as well as the moving distance of the dresser 19 on these areas 24, 25, 26 provides a difference of the abraded amount between these areas 24, 25, 26, whereby the intermediate area 25 of the polishing pad 12 has a larger amount of abrasion than the central area 24 and peripheral area 26 of the polishing pad 12. In FIG. 17, numerals 41 and 42 denote the locus of the central point and peripheral point, respectively, of the wafer 13 within the intermediate area 25 and peripheral area 26 of the polishing pad 12.

The conventional polishing pad shown in FIG. 3A and the polishing pad 12 in the polishing equipment 10 of the present embodiment shown in FIG. 2 were manufactured as samples used in the polishing equipment 10 shown in FIG. 1. These samples were used in the CMP process to polish a large number of sample wafers. The conventional polishing pad exhibited a considerable reduction in the polishing rate after polishing 1500 wafers, whereas the polishing pad 12 in the present embodiment exhibited an equivalent reduction after polishing 2000 wafers. Thus, the polishing pad 12 in the present embodiment exhibited the advantage of a larger operating time length over the conventional polishing pad.

FIG. 4 shows the configuration of a polishing pad of a first modification from the polishing pad 12 in the polishing equipment 10 of the first embodiment. The polishing pad 27 of this modification is such that the groove 21 in the central area 24 has a depth (d1) of 2.5 mm, with the groove 21 in the other areas 25 and 26 has a depth similar to that in the first embodiment. The abraded amount of the convex portions 22 is larger in the central area 24 than in the peripheral area 26. Thus, the large depth of the groove 21 in the central area provides a larger operating time length for the polishing pad 27. This further increases the operating time length of the polishing pad 27 of this modification.

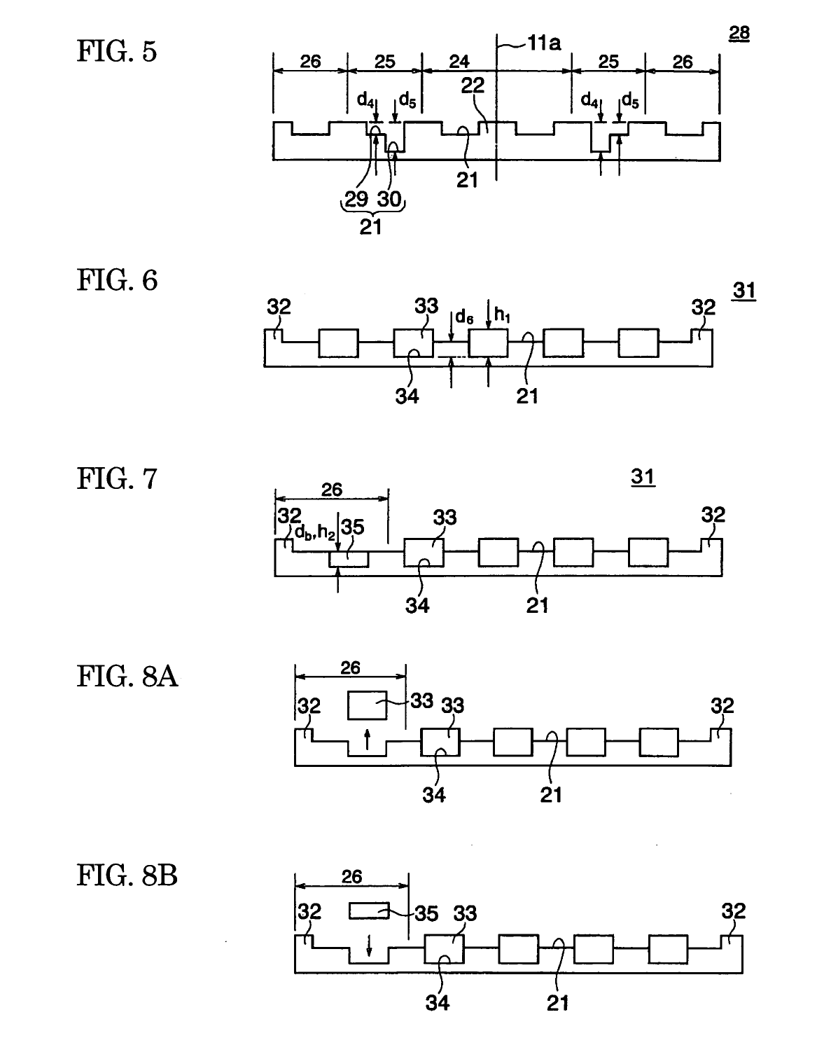

FIG. 5 shows the configuration of a polishing pad 28 of a second modification from the polishing pad 12 in the first embodiment. The polishing pad 28 of this modification is such that the groove 21 in the intermediate area 25 has a depth (d4) of 2 mm at an outer half-widthwise portion 29 and has a depth (d5) of 3 mm at an inner half-widthwise portion 30, with the groove in the other areas has a depth of 2 mm as in the case of the polishing pad 12. In other words, the groove 21 has a stepped bottom, wherein the depth of the groove 21 is larger in the inner half-widthwise portion than in the outer half-widthwise portion of the groove 21. This provides a configuration wherein the groove 21 in an area subjected to a larger abraded amount has a larger depth than the groove in another area subjected to a smaller abraded amount.

In the second modification, if the convex portions 22 are disappeared in the intermediate area 25 due to abrasion, the inner half-widthwise portion 30 of the groove 21 in the intermediate area 25 allows the slurry to flow toward the peripheral area 26 of the polishing pad 28. It is to be noted that either one of the inner portion 30 and outer portion 29 of the groove 21 should have a larger depth, and that the large-depth portion 30 need not necessarily have a width half the width of the groove 21, and may have a width ⅓, for example, of the width of the groove 21.

In addition, although the central area 24, intermediate area 25 and peripheral area 26 are specified by the distance from the center of the polishing pad 28, the specified radii are only exemplified, and thus may be experimentally determined by measuring the amount of abrasion. The depth of the groove 21 is changed stepwise in the above embodiment and modifications; however, the depth of the groove 21 may be continuously changed along the radial position of the groove 21.

FIG. 6 shows the configuration of a polishing pad in a polishing equipment according to a second embodiment of the present invention. FIG. 6 depicts the sectional view of the polishing pad 31 corresponding to the section of FIG. 2B. The body of the polishing pad 31 in the present embodiment has a substantially flat surface on which an array of square depressions 34 are arranged. A plurality of polishing blocks 33 are detachably received in the respective square depressions 34, to thereby form convex portions. The polishing pad 31 also has an outer periphery 32, which protrudes from the planar surface of the body and also function as a convex portion. For example, the block 33 has a height (h1) of 4 mm, and the square depression 34 has a depth (d6) of 2 mm as measured from the top of the flat surface of the body of the polishing pad 31.

FIG. 7 shows another state of the polishing pad 31 of FIG. 6. In this state, the polishing pad 31 has another block 35 having a height (h2) of 2 mm corresponding to the depth of the square depression 34 in the peripheral area 26, with the other area 24, 25 being similar to those in FIG. 6. The another block 35 is similar to the block 33 received in the other square depressions 34 except for the height thereof. The state of FIG. 7 is obtained by removing some of the polishing blocks 33 from the square depressions 34 in the peripheral area 26, as shown in FIG. 8A, followed by inserting the polishing blocks 35 in the empty square depressions 34, as shown in FIG. 8B.

The polishing equipment of the present embodiment includes a controller section or a computer on which a specific program runs. The computer in advance receives inputs specifying the arrangement of the square depressions. The computer receives the arrangement of the polishing blocks 33 and 35 on the polishing pad, and calculates the locus of the specific points of the wafer apart from one another in the radial direction of the wafer to obtain the polishing rates of the specific points, based on the conditions as well as the parameters including the rotational speed of the polishing pad 31, rotational speed and reciprocal movement of the polishing head 14 etc as well as the arrangement of the polishing blocks 33 and 35. The computer then calculates the polished profile of the wafer along the radial direction of the wafer 13.

Prior to the polishing of the wafer 13 by using the polishing equipment of the present embodiment, the arrangement of the polishing blocks 33 and 35 is obtained by simulation to achieve a uniform profile or smaller range of variation in the polishing rate between the points arranged along the radial direction. Based on the result of simulation, the arrangement of the polishing blocks 33 and 35 is modified. For example, if the simulation reveals a larger polishing rate at specific points, the number of polishing blocks 33 which are replaced by the polishing blocks 35 in the depressions near the specific points is calculated based on the calculated polishing rate. This suppresses the range of variation in the polishing rate within the surface of the wafer, to thereby obtain a uniform profile of the polished surface of the wafer.

According to research by the inventor, the polishing rate in the peripheral area from the outer periphery of the wafer to the radial position 15 mm apart from the outer periphery is generally higher than that in the other area of the wafer. In consideration of this tendency, the polishing blocks 33 in the peripheral area are replaced by the polishing blocks 35 to cancel the higher expected polishing rate and thereby suppress the range of variation in the profile of the polished surface.

In the above embodiment, polishing blocks include two types of blocks having different heights; however, the polishing blocks may include three or more types of blocks having different heights in order for achieving a more uniform profile of the polished surface. For example, polishing blocks having different height are provided based on the polishing rates of the specific points of the wafer calculated by the computer.

In addition, the polishing pad 12 may have a larger height of the polishing blocks in an area wherein the dresser 19 has a higher grinding rate for the polishing pad 12 to cause a larger abrasion, i.e., a high-grinding-rate area. In this configuration, the polishing pad 12 has a more uniform lifetime in the entire area of the polishing pad 12 to increase the overall lifetime of the polishing pad due to the increase of the lifetime of the convex portions in the high-grinding-rate area.

The conventional polishing pad shown in FIG. 3A was used in the polishing device shown in FIG. 1 for polishing wafers, and the polishing pad 31 of the embodiment shown in FIG. 6 was also used as a sample in the polishing device. Prior to operating the sample of the embodiment, the control section was used for the arrangement of the polishing blocks 33 and 35 for reducing the range of variation in the polishing rate. The results revealed that the conventional polishing pad exhibited ±10% of the variation in the polishing rate, whereas the polishing pad of the second embodiment exhibited ±5% of the variation in the polishing rate. Thus, the polished profile of the semiconductor wafers was significantly improved by the second embodiment.

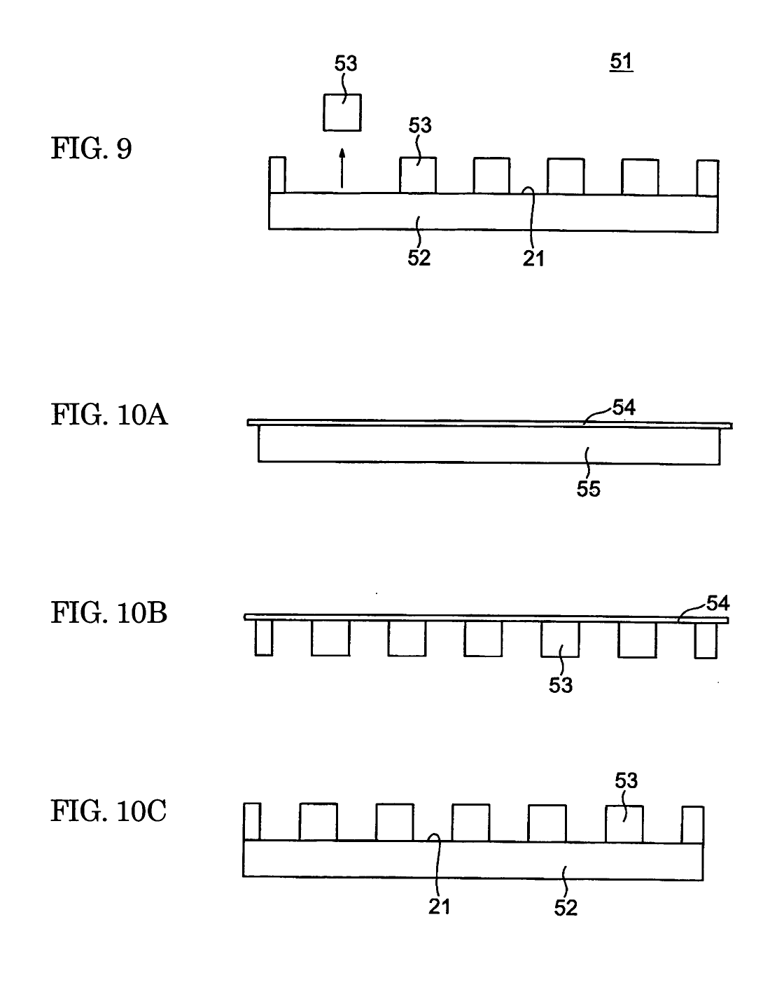

FIG. 9 shows a polishing pad of a first modification from the second embodiment of the present invention, wherein the bottom of the groove 21 is flat in the entire area for the polishing pad whereas the convex portions have different heights with respect to the bottom of the groove 21. The polishing pad 51 in the present modification includes a pad body 52 having a flat surface, and a plurality of polishing blocks 53 detachably fixed onto the flat surface to configure a groove 21 in the space between the polishing blocks 53. Control of the arrangement of the polishing blocks 53 by removing some of the polishing blocks 53 in an area controls the polishing rate in the area, similarly to the polishing pad in the second embodiment.

FIGS. 10A to 10C show a process for manufacturing the polishing pad 51 shown in FIG. 9. A fixing sheet 54 is first prepared from PET (polyethylene terephthalate), and is fixed onto a block board 55 by an adhesive, as shown in FIG. 10A. The block board 55 is then patterned to form an array of polishing blocks 53 arranged on the fixing sheet 54, as shown in FIG. 10B. The top of array of polishing blocks arranged on the fixing sheet 54 is then adhered onto the pad body 52, followed by removing the fixing sheet 54 from the array of polishing blocks 53, as shown in FIG. 10C to obtain the first modification from the second embodiment.

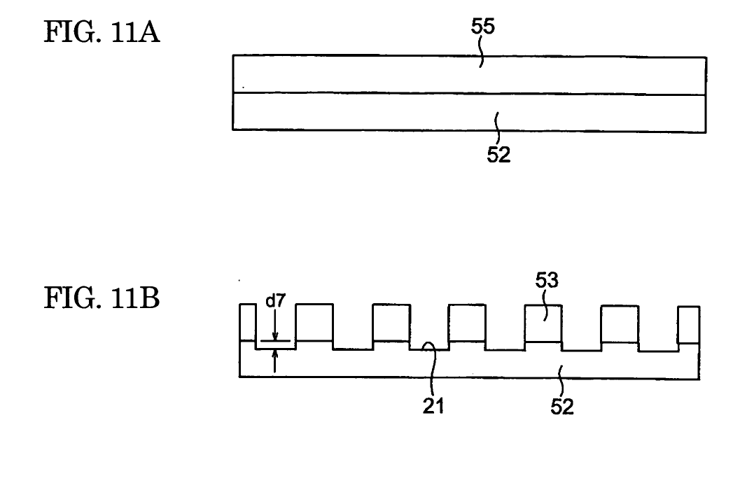

FIGS. 11A and 11B show another process for manufacturing the first modification of FIG. 9. A block board 55 and a body board 52 are prepared and fixed together by an adhesive, as shown in FIG. 11A, followed by patterning the block board 55 to form an array of polishing blocks 53. The top of the body board 52 is also etched in the patterning for assuring separation of the polishing blocks 53 from one another, as shown in FIG. 11B. The depth (d7) of patterning for the body board 52 may be around 0.5 mm, for example.

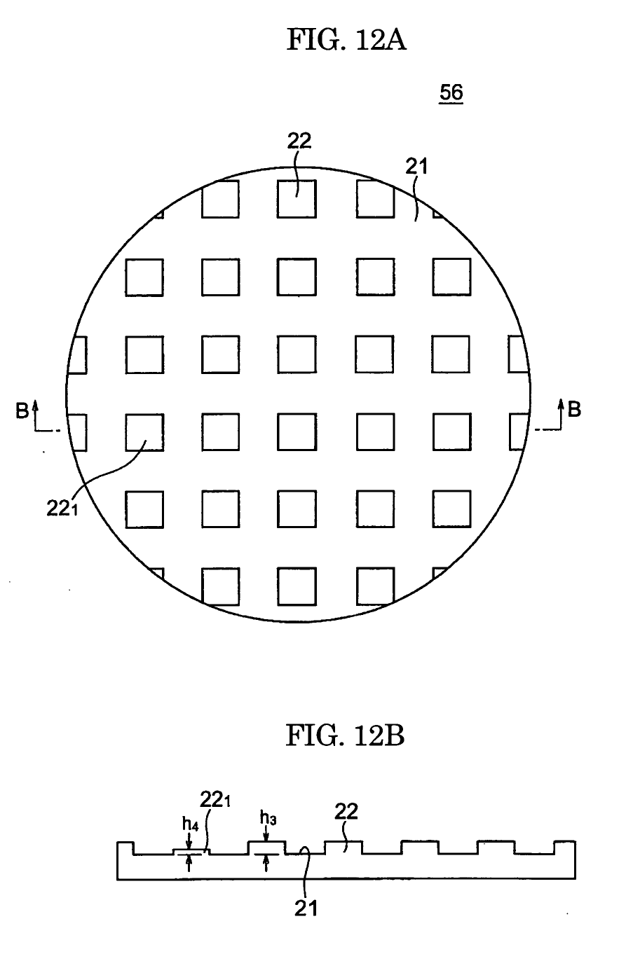

FIG. 12A shows the configuration of a polishing pad of a second modification from the second embodiment, and FIG. 12B is a sectional view taken along line B-B in FIG. 12A. The polishing pad 56 of the present modification has a flat bottom for the groove 21, and includes an array of convex portions 22 having a constant height (h3) in the central and intermediate areas. Some of the convex portions 22 in the peripheral area have the constant height (h3) whereas other of the convex portions 22 in the peripheral area have a smaller height (h4), which is about 1 mm or more smaller than h3. The other of the convex portions 22 in the peripheral area thus have substantially no polishing function for the wafer.

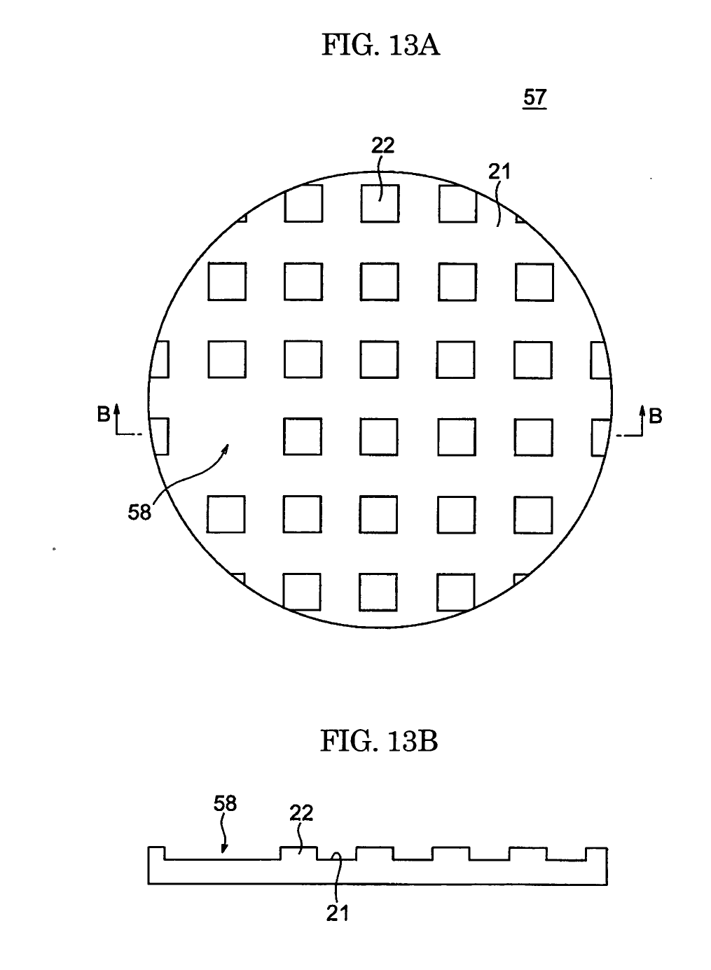

FIGS. 13A and 13B show, similarly to FIGS. 12A and 12B, a third modification from the second embodiment. The polishing pad 57 of the present modification has a flat bottom surface of the groove 21, and has an array of convex portions 22 in the entire area, wherein some of the convex portions 22 in the peripheral area are removed from the array in a specific area 58.

In the polishing devices 56, 57 according to the second and third modifications from he second embodiment, some of the convex portions 22 removed from the array or having a smaller height reduce the larger polishing rate in the peripheral area to suppress the range of variation in the polished profile of the wafer. In an alternative, the top of the convex portions 22 may be flat whereas the bottom of the groove 21 has different depths as measured from the top of the convex portions 22.

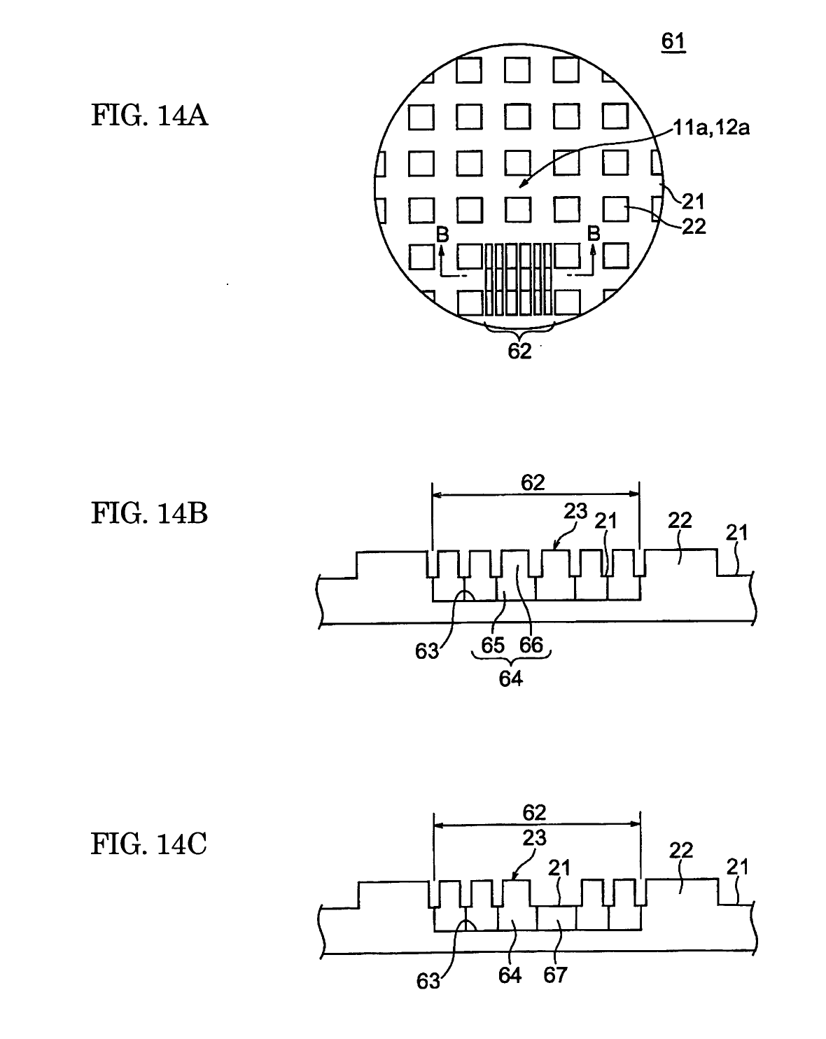

FIG. 14A shows the configuration of a polishing pad of a fourth modification from the second embodiment, and FIG. 14B shows a sectional view taken along line B-B in FIG. 14A. In the polishing pad 61 of the present modification, a specific area 62 is provided wherein the ratio of the area of the convex portions 22 to the entire area of the specific area 62 is controlled. More specifically, the specific area 62 is configured by a plurality of polishing blocks 64 detachably fixed onto a depression 63 having a larger depth than the groove 21 in the other area. Each block 64 has a horizontal area smaller than the horizontal area of the convex portions 22 in the other area.

The polishing blocks 64 each have a convex portion 66 having a top flush with the top of the convex portions 22, and a peripheral groove portion 65 which defines the bottom of the groove 21. For controlling the area ratio in the specific area 62, some of the polishing blocks 64 having the convex portion 66 are replaced by other polishing blocks 67 having a smaller area of the convex portion 66 or having no convex portion 66 at all.

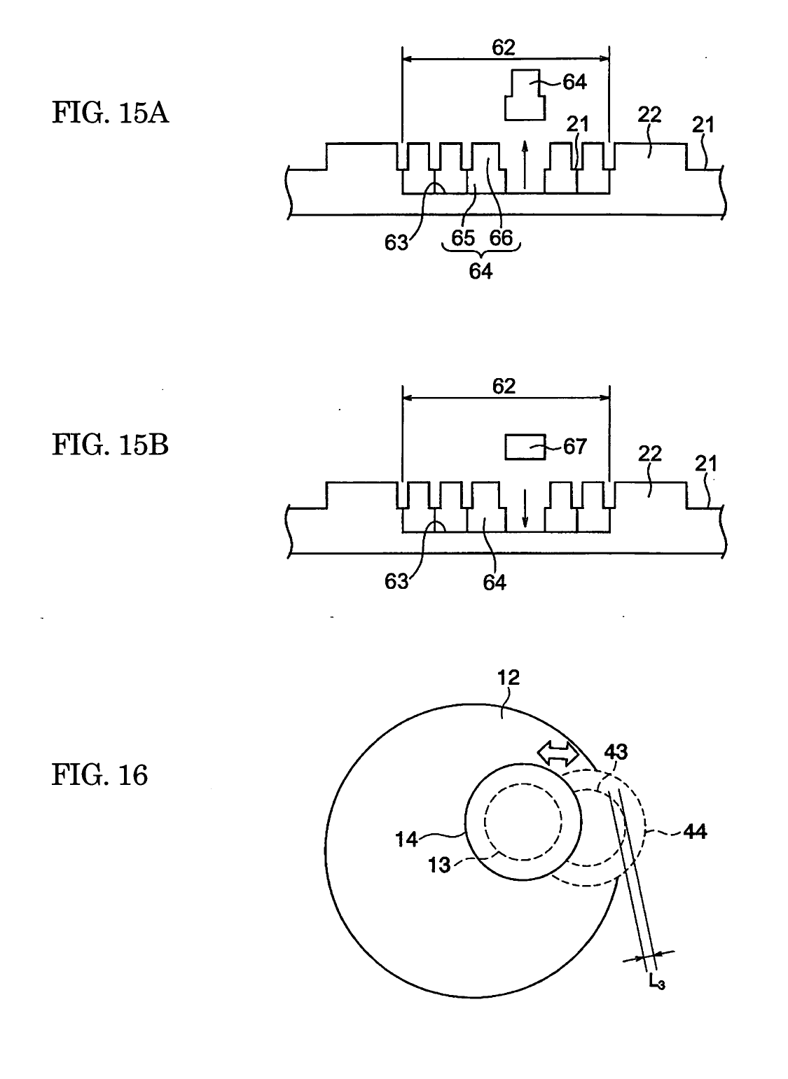

FIG. 14C shows another state of the specific area 62 shown in FIG. 14B, wherein one of the polishing blocks 64 having the convex portion 66 is replaced by another block 67 having a no convex portion 66 and defining only the bottom of groove 21. In this sate of the polishing pad 61 shown in FIG. 14, the specific area 62 has a smaller polishing rate than the other area of the polishing pad 61 due to the block 67 having no convex portion 66. FIGS. 15A and 15B show the way of replacement of the block 64 by the block 67, wherein FIG. 15A shows the removal of the block 64 and FIG. 15B shows insertion of the block 67 instead of the block 67.

In the present modification, the plurality of polishing blocks 64 each having a horizontal area smaller than the horizontal area of the convex portions 22 in the other area allows finer adjustment of the polishing rate in the specific area 62 depending on the number and/or location of the polishing blocks 64 to be replaced. This provides a finer adjustment in the polished profile for the wafer. In addition, if the polishing blocks 64 are subjected to abrasion, the abraded polishing blocks 64 may be replaced by new polishing blocks 64, thereby increasing the operating time length of the polishing pad 61.

In addition, the convex portions 22 in the other area other than the specific area 62 may have a configuration similar to that shown in FIG. 6. Further, the polishing pad 12 shown in FIGS. 2A and 2B or the polishing pad 31 shown in FIG. 6 may also have such a specific area, wherein the convex portions in the specific area have a horizontal area smaller than the horizontal area of the convex portions in the other area.

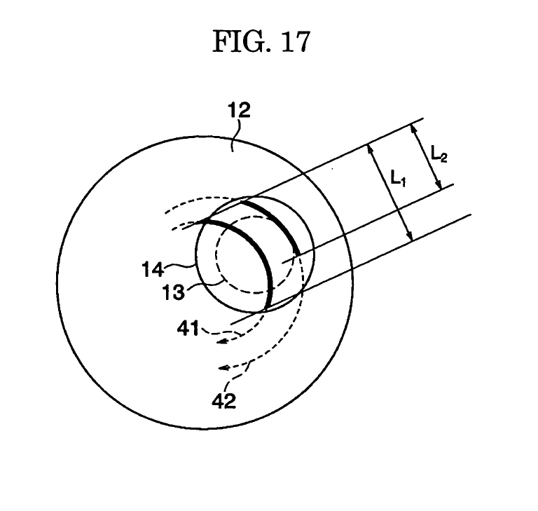

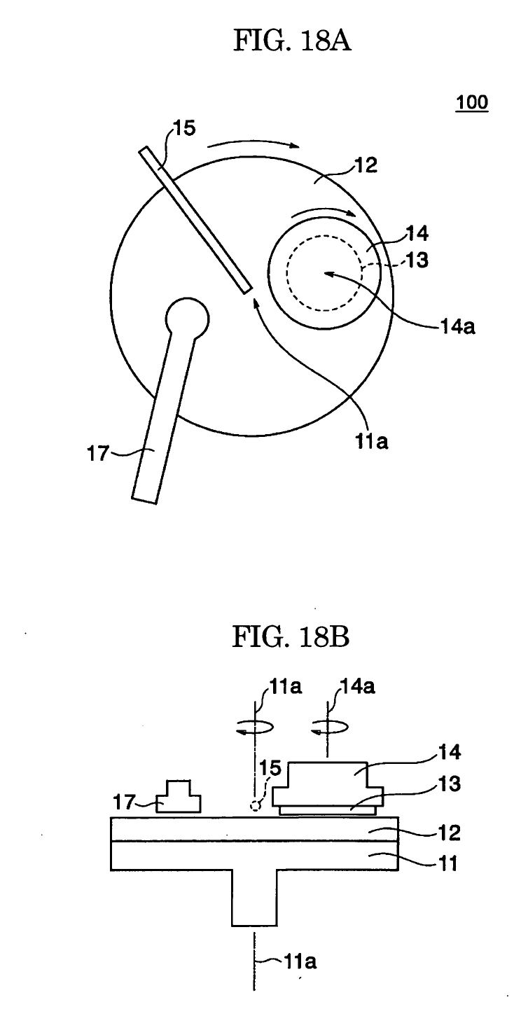

FIG. 16 shows a polishing device using a polishing method according to a third embodiment of the present invention. In the peripheral area having a larger polishing rate than the central area, the polishing method uses a specific technique instead of using the arrangement of the polishing blocks 33 and 35 such as described in the second embodiment.

More specifically in the method of the present embodiment, the conventional polishing pad shown in FIG. 3A is employed while using an overhanging technique. The overhanging technique shown in FIG. 16 is such that the polishing head 14 mounting thereon a wafer 13 has an overhanging position at which the polishing head 14 overhangs the polishing pad 12 or a portion of the polishing head 14 protrudes from the periphery of the polishing pad 12. In FIG. 16, dotted lines 43 and 44 show the overhanging state of the polishing head 14 and wafer 13, respectively. The overhanging portion of the polishing head 14 or overhanging wafer 13 allows the peripheral area of the wafer 13 to have a reduced polishing rate, to suppress the excessive polishing rate, thereby providing a superior profile of the polished wafer.

In FIG. 17, the distance L3 between the periphery of the overhanging wafer 13 and the periphery of the polishing pad 12 as well as the overhanging time length can be determined by calculating the locus of the points of the wafer passing on the polishing pad 12 in a simulation. The control section calculates the length of the locus of the points of the wafer passing on the polishing pad without overhanging, and compensate the difference in the length by reducing the length of locus while using the overhanging.

Since the above embodiments are described only for examples, the present invention is not limited to the above embodiments and various modifications or alterations can be easily made therefrom by those skilled in the art without departing from the scope of the present invention.

What is claimed is:

1. A polishing equipment comprising:
a polishing head for mounting thereon a wafer to be polished and rotating the wafer with respect to a central axis thereof; and
a polishing pad rotating with respect to a central axis thereof and having a polishing surface for polishing a main surface of the wafer, wherein:
said polishing surface has thereon a plurality of convex portions defining therebetween a groove for passing therethrough slurry, and at least a widthwise portion of said groove in a first area of said polishing surface has a depth larger than a depth of a corresponding at least widthwise portion of said groove in a second area of said polishing surface.

2. The polishing equipment according to claim 1, wherein said first area has a lower expected polishing rate with respect to the wafer than said second area.

3. The polishing equipment according to claim 1, wherein said first area has a higher abrasion rate of said convex portions than said second area.

4. The polishing equipment according to claim 3, wherein a rotational direction of said polishing pad is same as a rotational direction of said polishing head, and said polishing surface consecutively has a central area, intermediate area and a peripheral area as viewed from a center of said polishing surface, said intermediate area configuring said first area, said central area and said peripheral area configuring said second area.

5. The polishing equipment according to claim 4, wherein said groove in said central area has a depth larger than a depth of said groove in said peripheral area.

6. The polishing equipment according to claim 1, wherein said groove forms a lattice on said polishing surface.

7. The polishing equipment according to claim 1, wherein another widthwise portion other than said at least widthwise portion of said groove has a common depth in said first and second areas.

8. The polishing equipment according to claim 1, wherein said polishing surface includes a flat surface configuring a bottom surface of said groove, a plurality of depressions formed in said flat surface, and a plurality of polishing blocks received in respective said depressions and having a height not smaller than a depth of said depressions measured from said flat surface.

9. The polishing equipment according to claim 1, wherein said polishing surface includes a flat surface configuring a bottom surface of said groove, and an array of polishing blocks arranged on said flat surface, at least some of said polishing blocks in said first area have a height larger than a height of said polishing blocks in said second area.

10. The polishing equipment according to claim 9, wherein at least a part of said polishing blocks are detachably fixed onto said flat surface.

11. A polishing equipment comprising:
a polishing head for mounting thereon a wafer to be polished and rotating the wafer with respect to a central axis thereof; and
a polishing pad rotating with respect to a central axis thereof and having a polishing surface for polishing a main surface of the wafer, wherein:
said polishing surface includes an array of convex portions attached or formed on said polishing surface to configure therebetween a groove.

12. The polishing equipment according to claim 11, wherein an area ratio of total area of said convex portions in a first area to an entire area of said first area is smaller than an area ratio of total area of said convex portions in a second area to an entire area of said second area.

13. The polishing equipment according to claim 11, wherein some of said convex portions in an area of said polishing surface are removed.

14. The polishing equipment according to claim 11, wherein said polishing surface includes a flat surface configuring said groove, a plurality of depressions formed on said flat surface, and a plurality of polishing blocks received in respective said depressions, at least some of said polishing blocks having a height not smaller than a depth of said depressions measured from said flat surface.

15. A method for polishing an object by using a polishing equipment including a polishing head mounting thereon and rotating the object, and a polishing pad having a polishing surface for polishing a surface of the object, said method comprising the steps of:
calculating a distance of locus of each of a plurality of points on said surface of the object apart from one another in a radial direction during moving of said each of said plurality of points upon rotation of the object and said polishing surface, said plurality of points corresponding to a plurality of areas of said polishing surface; and
calculating an expected polishing rate of said each of said plurality of points based on said calculated distance.

16. The method according to claim 15, further comprising the step of controlling a height of a groove in each of said areas of said polishing surface based on said calculated, expected polishing rate to achieve a uniform polishing rate in the object during polishing the object.

17. The method according to claim 15, further comprising the step of allowing a portion of said surface of the object to protrude from a periphery of said polishing surface and overhang outside said polishing surface during polishing the object.
